(19) United States
(12) Patent Application Publication
(10) Pub. No.: US 2024/0097406 A1
(43) Pub. Date: Mar. 21, 2024

(54) FLARED LASER DIODE ARRAY

(71) Applicant: Lumentum Operations LLC, San Jose, CA (US)

(72) Inventors: Martin H. MUENDEL, Oakland, CA (US); Matthew Glenn PETERS, Menlo Park, CA (US); James J. MOREHEAD, Oakland, CA (US); John G. BAI, San Jose, CA (US); Victor ROSSIN, Mountain View, CA (US)

(21) Appl. No.: 18/066,728

(22) Filed: Dec. 15, 2022

Related U.S. Application Data
(60) Provisional application No. 63/376,483, filed on Sep. 21, 2022.

(51) Int. Cl. H01S 5/40; H01S 5/02255; H01S 5/028; H01S 5/10

(52) U.S. Cl. CPC H01S 5/4087; H01S 5/02255; H01S 5/028; H01S 5/1082

(57) ABSTRACT

In some implementations, a laser diode array may comprise a cavity that includes a rear facet and a front facet and multiple emitters that are transversely single mode and disposed within the cavity. In some implementations, the multiple emitters each include a seeding section having a constant emitter width that is single mode at the rear facet and a flared section having a monotonically expanding emitter width that increases adiabatically over a majority of a length of the cavity such that outputs from the multiple emitters are single mode at the front facet. In some implementations, the emitter width is less than twenty micrometers at the front facet.

### CROSS-REFERENCE TO RELATED APPLICATION

This patent application claims priority to U.S. Provisional Patent Application No. 63/376,483, filed on Sep. 21, 2022, and entitled “FLARED LASER DIODE ARRAY.” The disclosure of the prior application is considered part of and is incorporated by reference into this patent application.

### TECHNICAL FIELD

The present disclosure relates generally to a waveguide structure and to a single mode emitter that can be used in a very-broad-area, high-power chip or a single mode array in high-power, high-brightness applications.

### BACKGROUND

When light propagates in free space, a transparent homogeneous medium, a waveguide structure, or an optical resonator, there are certain electric field distributions, referred to as modes, that are self-consistent during propagation. For example, for light propagating in a waveguide, the self-consistency condition may be that the shape of the complex amplitude profile in transverse directions must remain constant. For a given optical frequency, a waveguide has only a finite number of guided propagation modes. A single mode waveguide (e.g., a single mode fiber) has only a single guided mode per polarization direction.

### SUMMARY

In some implementations, a laser diode array includes a cavity that includes a rear facet and a front facet; and multiple emitters that are transversely single mode and disposed within the cavity. In some implementations, the multiple emitters each include: a seeding section having a constant emitter width that is single mode at the rear facet, and a flared section having a monotonically expanding emitter width that increases adiabatically over a majority of a length of the cavity such that outputs from the multiple emitters are single mode at the front facet, wherein the emitter width is less than twenty micrometers at the front facet.

In some implementations, a multi-wavelength source includes: a laser diode array that includes: a cavity that includes a rear facet and a front facet; and multiple emitters that are transversely single mode and disposed within the cavity, wherein the multiple emitters each include: a seeding section having a constant emitter width that is single mode at the rear facet, and a flared section having a monotonically expanding emitter width that increases adiabatically over a majority of a length of the cavity such that a set of beamlets output from the multiple emitters are single mode at the front facet, wherein the emitter width is less than twenty micrometers at the front facet. In some implementations, the multi-wavelength source includes: a fast-axis collimation (FAC) lens to collimate the set of beamlets in a fast-axis direction; a slow-axis collimation (SAC) lens to collimate the set of beamlets in a slow-axis direction; and a grating to direct the set of beamlets toward an output coupler.

In some implementations, an emitter includes a rear facet; a front facet; and a transversely single mode cavity that includes a seeding section and a flared section arranged between the rear facet and the front facet, wherein the seeding section has a constant emitter width that is single mode at the rear facet, wherein the flared section has a monotonically expanding emitter width that increases adiabatically over a majority of a length of the cavity such that an output from the emitter is single mode at the front facet, and wherein the emitter width is less than twenty micrometers at the front facet.

### BRIEF DESCRIPTION OF THE DRAWINGS

FIGS. 1A-1C are diagrams illustrating an example implementation of a flared laser diode array described herein.

FIGS. 2A-2D are diagrams illustrating example plots related to performance of a flared laser diode array described herein.

FIG. 3 is a diagram illustrating an example implementation of a multi-wavelength source that includes a flared laser diode array described herein.

### DETAILED DESCRIPTION

The following detailed description of example implementations refers to the accompanying drawings. The same reference numbers in different drawings may identify the same or similar elements.

One conventional approach to achieve a single lateral mode laser is to reduce the stripe width of a broad-area diode laser (BAL). For example, when the stripe width of a BAL is reduced, the laser will typically support fewer optical modes in the lateral direction, and only one fundamental lateral mode will lase at a size scale of a few microns. However, the conventional approach to reduce the BAL stripe width is typically associated with power and efficiency drops because the reliable lasing power of a diode laser is typically limited by the onset of facet degradation, which depends on the optical intensity on the facet. Therefore, a much narrower emitter width typically results in a much lower lasing power per emitter. Furthermore, the relative internal loss at the laser stripe side walls is typically increased, whereby a narrow stripe width may result in lower slope efficiency of the laser. A lower lasing efficiency may cause a relatively lower optical power per laser because of the extra heat that needs to be extracted during operation. Nevertheless, several versions of single lateral mode diode lasers with narrow emitter widths have been designed, each of which suffers from one or more drawbacks.

For example, in some cases, a slab-coupled optical waveguide laser (SCOWL) array may include two emitter devices and utilize slab-coupling of higher order modes to emit in a large single-spatial mode. In a SCOWL design, a very narrow emitter width (e.g., 4.7 micrometers (μm)) is used to ensure strict single lateral mode lasing, and a slow-axis beam quality of each emitter is very close to a diffraction limit. However, the efficiency and power level of the laser array is relatively low. For example, an array of twenty (20) SCOWL emitters with a 5 millimeter (mm) cavity length that is bonded junction-down can achieve only 15 watts (W) total power. In a SCOWL array associated with a 100 μm pitch, the total width of the 15 W laser array is 2 mm, whereby the lasing power density of the SCOWL array equals 75 W per centimeter (cm) in a lateral direction.

In another potential approach, a single emitter array laser (SEAL) also has a typical emitter width below 5 μm to ensure single lateral mode laser operation. For example, in one design, fifty (50) emitters with an emitter width of only 3.0 μm each may enable a 50 W continuous wave (CW) power at a 200 μm pitch, which translates to a lasing power density of only 50 W per cm. In other examples, the linear power density of a SEAL may be increased to 260 W per cm using 195 emitters in a laser bar, resulting in a power rating up to 1.33 W per emitter and a laser efficiency of approximately 60%. However, despite the improved linear power density and power rating, the SEAL design still has an emitter width below 5 μm.

In general, the SCOWL and SEAL designs described above are examples of single lateral mode diode lasers with narrow emitter widths (e.g., below 5 μm). Another potential approach to address the fundamental limitations associated with the narrow emitter width while keeping the lateral single mode lasing is to employ a more sophisticated laser structure, such as a tapered laser structure with a much larger emitter width. For example, in some cases, an integrated master oscillator power amplifier (MOPA) structure may include a tapered amplifier section. By carefully designing the oscillator and the amplifier sections, the etched trenches in the oscillator section, and the tapering angles of the amplifier section, a quasi-single lateral mode lasing may be achieved with an emitter width up to 150 μm at the laser facet. The most optimized MOPA laser has a reported power level of 8 W and a beam brightness of 660 MW/cm²-str. The linear power density of such a MOPA laser equals 533 W per cm and the beam quality, M_{SA}², is less than 1.4. However, such a laser design suffers from drawbacks that include a 15-25% laser power in the side lobes and a laser beam from the MOPA laser being astigmatic with a virtual source position in the lateral direction varying during operation of the MOPA laser. Such an unstable virtual source and the considerably high power losses in the side lobes may pose challenges for fiber laser coupling, and therefore limit the applications of these MOPA lasers.

In some implementations, as described herein, an adiabatically flared laser diode array may have a design that can scale emitter width while maintaining power density (e.g., the flared laser diode array may provide a linear power density greater than 1000 W per cm). For example, in some implementations, the adiabatically flared laser diode array may include an array of adiabatically broadened single mode emitters (e.g., a flared chip array) in which each single mode emitter has a width up to 15-20 μm, compared to conventional narrow stripe width lasers that typically have an emitter width that is less than or equal 5 μm. The flared laser diode array may be used as a very-broad-area, high-power chip or as a single mode array with wavelength beam combination (WBC) in high-power, high-brightness, and/or low-cost applications that may require near diffraction-limited beam quality (e.g., pumps and/or direct diodes, among other examples). In some WBC applications, wavelength feedback may be provided from external gratings (e.g., the flared laser diode array does not require any gratings), or the flared laser diode array may include internal gratings (e.g., for high-power high-brightness pump applications).

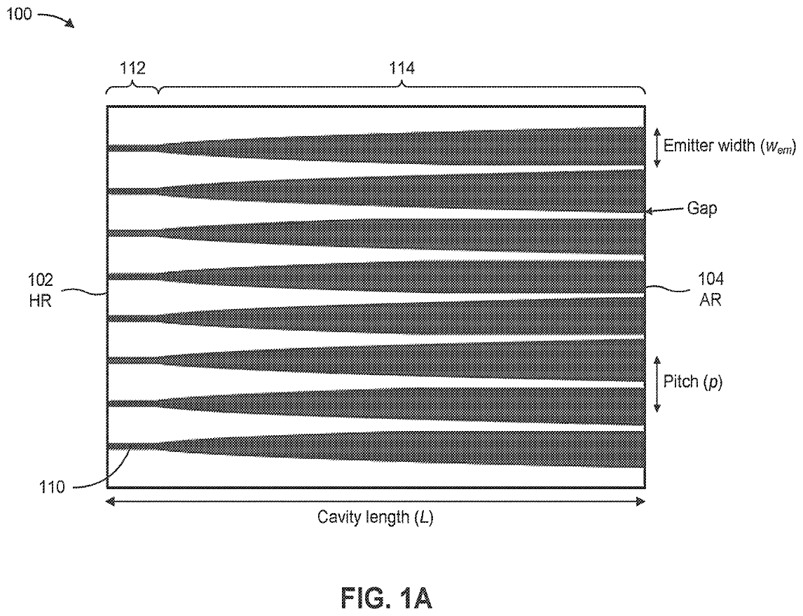

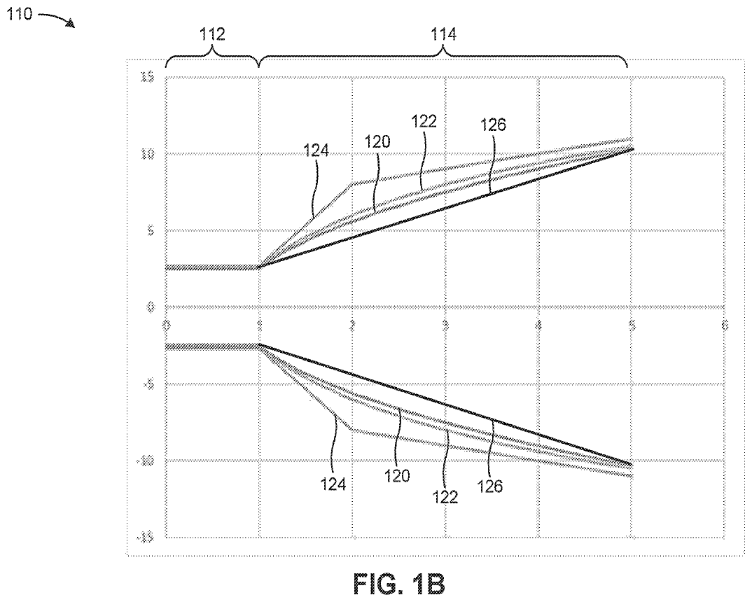

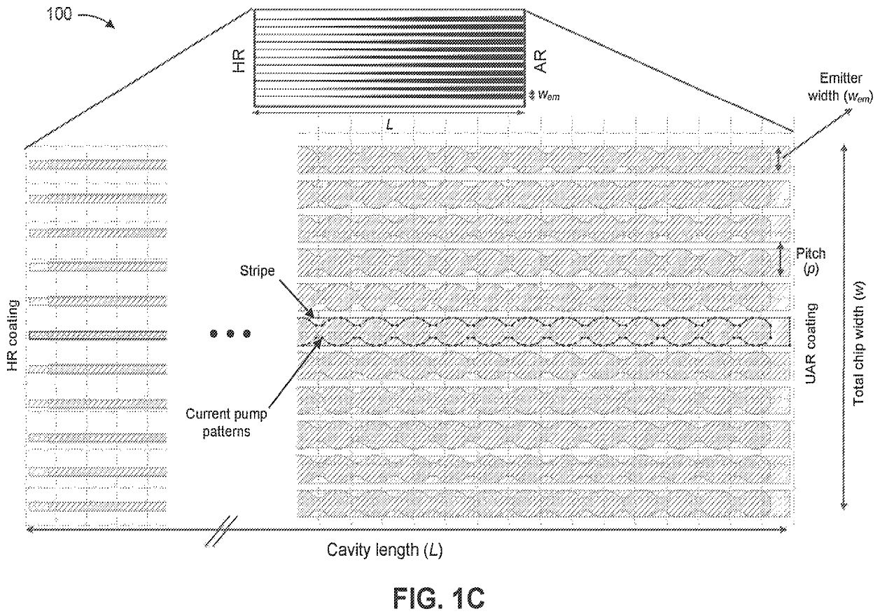

FIGS. 1A-1C are diagrams illustrating an example implementation of a flared laser diode array 100 described herein. For example, as shown in FIGS. 1A-1C and described in further detail herein, the flared laser diode array 100 includes a cavity with a rear facet 102 and a front facet 104 and multiple emitters 110 that are transversely single mode and disposed within the cavity. In some implementations, as shown, the rear facet 102 may include a highly reflective (HR) coating and the front facet 104 may include a low reflectivity coating (e.g., an anti-reflective (AR) coating or an ultra-anti-reflective (UAR) coating). As further shown, the multiple emitters 110 may each include a seeding section 112 that has a constant emitter width that is single mode at the rear facet 102 and a flared section 114 having a monotonically expanding emitter width that increases adiabatically over a majority of a length of the cavity (e.g., the flared section 114 has a length that is at least 50% of a cavity length, L, which may be 5.5 millimeters in one example design). Accordingly, because the emitter width expands monotonically and adiabatically over the length of the flared section 114, single mode propagation that is established in the seeding section 112 is maintained in the flared section, whereby outputs from the multiple emitters 110 are single mode at the front facet 104. In some implementations, as described herein, the adiabatically flared design of the various emitters 110 may be used to scale the emitter width while maintaining power density, where the flared laser diode array 100 may be used as a very-broad-area, high-power chip or as a single mode array with wavelength beam combination (WBC) in high-power, high-brightness applications that require near diffraction-limited beam quality.

Accordingly, unlike a traditional BAL, the adiabatically flared laser diode array 100 may include an array of emitters 110 with each emitter 110 having a precisely designed flare structure to produce an array of spots at the output (e.g., at the front facet 104), with each spot being much wider than a conventional single mode emitter. Furthermore, the spots produced by the various emitters 110 are packed together closely to minimize the total emitting width. For example, as shown, a gap (e.g., about 2-4 μm) may be provided between adjacent emitters 110 to ensure that the various emitters 110 are packed together closely but are far enough apart to avoid significant evanescent coupling. For example, evanescent coupling may generally occur between adjacent emitters 110 when there is no gap, a small gap, and/or an overlap between the adjacent emitters 110. Accordingly, the gap may be provided between adjacent emitters 110 to prevent evanescent coupling, which is generally detrimental to operation in an unlocked chip and/or in WBC applications.

In some implementations, using the flared design shown in FIGS. 1A-1C, single lateral mode lasing can be maintained up to a 15-20 μm beam width at the front facet 104 of each emitter 110 (e.g., an emitter width (wₑₘ) at the front facet 104 may be in a range from 15-20 μm), which exceeds the typical emitter width of less than 5 μm for the SCOWL and/or SEAL designs described above. Furthermore, the value of wₑₘ at the front facet 104 in combination with the gap between adjacent emitters 110 may define a pitch, p, of the laser diode array 100 (e.g., a center-to-center distance between adjacent emitters 110). For example, in a design where wₑₘ at the front facet 104 is 15 μm and the gap between adjacent emitters 110 is 2 μm, the pitch, p, of the laser diode array 100 would be 17 μm. Furthermore, a chip fill factor may be related to the values of wₑₘ at the front facet 104 and the pitch p (e.g., the chip fill factor, or portion of the total chip width w that is occupied by the emitters 110, may be defined as the value of wₑₘ at the front facet 104 divided by the pitch p).

In some implementations, the (straight) seeding section 112 of the various emitters 110 included in the adiabatically flared laser diode array 100 may have a constant emitter width (wₑₘ) sized to be robustly single-lateral-mode. For example, the seeding section 112 may be a relatively narrow straight section near the HR coating to enforce (or establish) single mode lasing, and the emitter width may then gradually expand in the flared section 114. For example, the emitter width may expand monotonically, starting from the end of the seeding section 112, and the expansion of the emitter width over the remaining length of the cavity may remain adiabatic throughout to maintain single mode propagation even as the waveguide becomes multimoded. For example, a minimum length of the rear-side single mode seeding section 112 for the lateral single mode lasing may depend on total losses (e.g., mirror and internal losses of the fundamental Gaussian mode and the higher order mode) because the material gains for the fundamental or the next higher lateral modes are generally similar. For example, in some implementations, the minimum length of the seeding section 112 may correlate to parameters such as an epitaxial material, a layer process, and/or a material used for the HR and AR coatings.

In some implementations, in order to establish robust seeding and enforce single mode propagation within the seeding section 112, the seeding section 112 may have a constant emitter width, w, that satisfies the following expression:

$$w < ( 0.45 - 0.65 ) * \frac{λ}{\sqrt{( {n}^{2} - {n}_{0}^{2} )}} ,$$

where λ is a lasing wavelength, n is an effective index of the single mode in the waveguide region associated with each emitter 110, and n₀ is a refractive index of the single mode outside the waveguide region associated with each emitter 110. Accordingly, the emitter width in the seeding section may satisfy a single mode seeding threshold that is based on a value of λ, a value of n, and/or a value of n₀. Furthermore, in cases where the waveguide region provides a relatively weak gain and/or index guiding, the seeding section 112 may have a relatively wider emitter width. On the other hand, a narrower emitter width may be needed in the seeding section 112 to provide stronger gain and/or index guiding. However, the wider emitter width that may be allowed in the seeding section 112 when there is weaker index guiding may have a trade-off with regard to potential evanescent coupling between adjacent emitters 110, which is generally harmful for the WBC applications and also typically detrimental to beam quality for non-WBC applications. Nonetheless, there may be certain instances in which evanescent coupling between adjacent emitters 110 is acceptable or desired, whereby wider emitter widths may be used for such applications.

In some implementations, in order to maintain adiabaticity over the length of the flared section 114, the rate of beam expansion (e.g., a rate at which the emitter width expands over the length of the flared section 114) should be small compared with the local beam divergence, as shown in the following expression:

$$\frac{dw}{dz} ≪ {NA}_{beam} ( z ) = \frac{λ}{π * n * w ( z )} ,$$

where dw/dz is the rate of beam expansion, w(z) is the beam radius, z is a position along the direction of propagation, NA_{beam}(z) is the divergence at that position, λ is the wavelength, and n is the chip waveguide effective index.

In some implementations to achieve the widest possible output spot with maximum adiabaticity, the flare within the flared section 114 may be designed to maintain a uniform adiabaticity along an entire length of the flared section 114 (e.g., dw/dz should be a constant or near-constant fraction of NA_{beam}). In such cases, the rate of beam expansion (e.g., a rate at which the emitter width expands) may be high in a region of the flared section 114 that is near the rear seeding section 112 of the emitter 110 (e.g., where the beam width is small and the divergence is high). On the other hand, the rate of beam expansion may be relatively lower in a region of the flared section 114 nearer to the front facet 104 of the emitter 110 (e.g., where the beam width is large and the divergence relatively low). Accordingly, in some implementations, the flare of the flared section 114 may be shaped such that the beam width is a curve with a high initial expansion rate that subsequently slows down as the emitter width increases.

In some implementations, solving the differential equation for the ideal curve for the beam width shape yields w(z)=(C_{1z}+C₂)^{1/2}, which is a parabola with an axis oriented along a propagation axis of each emitter 110. It will be appreciated, however, that other suitable curved or piecewise straight flare shapes can be used in the flared section 114, with a unifying design parameter being that the waveguide region of each emitter 110 is expanding monotonically over some or all of a length of the flared section 114. Furthermore, in some implementations, another design parameter for the flared section 114 may be that the waveguide region is expanding within the flared section 114 by a minimum amount relative to the diode wavelength. For example, in some implementations, the waveguide region may expand within the flared section 114 by about 10 times the diode wavelength (e.g., about 10 μm for a laser diode in an 800-1100 nanometer (nm) range). Additionally, or alternatively, the flared shape of the flared section 114 may include at least two sections in which the beam width expands while traveling toward the output at the front facet 114, with the region of the flared section 114 closer to the output having a larger beam (or emitter) width and a lower rate of beam (or emitter width) expansion.

Additionally, or alternatively, a flare with a constant (e.g., linear) expansion rate may provide acceptable performance. For example, FIG. 1B illustrates an example of beam expansion in an emitter 110 that may be included in the flared laser diode array 100, where the horizontal axis represents z (e.g., a propagation direction in mm) and the vertical axis represents w(z) (e.g., a beam lateral size in μm). As shown in FIG. 1B, the emitter 110 includes a straight seeding section 112 with a constant emitter width (e.g., about 5 μm in the example designs shown in FIG. 1B) and a flared section 114 in which the emitter width expands monotonically and increases adiabatically over some or all of the flared section 114, which spans a majority of a length of the cavity of the emitter 110. Referring to FIG. 1B, curve 120 corresponds to a design in which the flared section 114 has the ideal parabolic shape (e.g., a square root, representing an ideal beam expansion) and curve 122 corresponds to a design in which the flared section 114 has a logarithmic shape. In the designs shown by curves 120 and 122, a rate at which the emitter width expands over the flared section 114 is a constant fraction or a near-constant fraction of a numerical aperture of a beam traveling in the propagation direction. Alternatively, curve 124 corresponds to a design in which the flared section 114 has a piecewise straight beam expansion with multiple sub-sections (e.g., two sub-sections in the example shown in FIG. 1B), where the emitter width expands at different linear rates in each sub-section. Alternatively, because the curve 120 that corresponds to the ideal parabolic shape is relatively close to a straight line, as shown by curve 126, the flared section 114 may have a linear shape or a linear flare in which the expansion rate of the emitter width is constant (or linear) over the length of the flared section 114. Accordingly, as shown in FIG. 1B, there are various designs or shapes that can be used in the flared section to adiabatically increase the emitter width over the length of the flared section.

For example, in FIG. 1B, curves 120, 122, 124, and 126 each represent suitable designs to monotonically and adiabatically expand a beam width from a constant beam width that is used to establish or enforce single mode propagation in the seeding section 112 to a wider beam width at the front facet 104 while maintaining single mode propagation in the flared section 114. For example, in FIG. 1B, z=0 is the rear facet 102, the seeding section 112 from z=0 to z=1 is a single mode waveguide with a constant emitter width of 5 μm, z=5 is the front (output) facet 104 with a maximum emitter width of 20 μm and a minimum emitter width of 15 μm, and curves 120, 122, 124, and 126 each represent possible flare shapes to adiabatically expand the emitter width from the constant emitter width in the seeding section 112 to the final emitter width at the front facet 104.

In some implementations, the shape of the flared section 114 of the waveguide may be qualitatively similar to a desired beam width curve, although the shape may not be exactly proportional. For example, as the flared section 114 of the waveguide becomes wider, the fundamental mode increases sublinearly relative to the waveguide. Accordingly, the optimal waveguide shape may be distorted from the curve 120 corresponding to the ideal parabolic beamwidth. Additionally, other features such as teeth or serrations in the waveguide design or patterning of the electrodes may be used to tailor the gain profile and refractive-index profile to assist in maintaining single mode operation over the flared section. For example, FIG. 1C illustrates an example of a serrated pattern in which the gain is peaked or maximized at the center of the waveguide and falls off in regions toward or near the edges of the waveguide to maximize the gain for the fundamental mode and avoid amplifying secondary modes.

Accordingly, the teeth or serrated pattern may increase the amount that the emitter width can be expanded in the flared section 114. For example, without the teeth or serrated pattern, a particular emitter width at the front facet 104 may not produce a single mode output, but adding the teeth or serrated pattern may maintain single mode operation (e.g., a taper or flare alone may allow single mode operation to be maintained in the flared section 114 up to 15 μm, and adding the teeth or serrated pattern may allow single mode operation to be maintained in the flared section 114 up to 20 μm). Furthermore, for an output spot size of ˜3× the nominal single mode width of ˜5 μm, the output beam remains nearly flat in phase and therefore has a non-astigmatic waist near the front facet 104 and little distortion by effects such as thermal lensing. Because each emitter cavity is formed by the chip end facets 102 and 104, the emitters 110 may have just enough separation at the output (e.g., a few microns) to avoid crosstalk and ensure independent lasing with a uniform array of spots and smooth, Gaussian-like far field. Otherwise, when the emitters 110 are positioned too close to one another, deleterious crosstalk becomes evident through optical spots in the near and far fields.

As indicated above, FIGS. 1A-1C are provided as an example. Other examples may differ from what is described with regard to FIGS. 1A-1C. The number and arrangement of devices shown in FIGS. 1A-1C are provided as an example. In practice, there may be additional devices, fewer devices, different devices, or differently arranged devices than those shown in FIGS. 1A-1C. Furthermore, two or more devices shown in FIGS. 1A-1C may be implemented within a single device, or a single device shown in FIGS. 1A-1C may be implemented as multiple, distributed devices. Additionally, or alternatively, a set of devices (e.g., one or more devices) shown in FIGS. 1A-1C may perform one or more functions described as being performed by another set of devices shown in FIGS. 1A-1C.

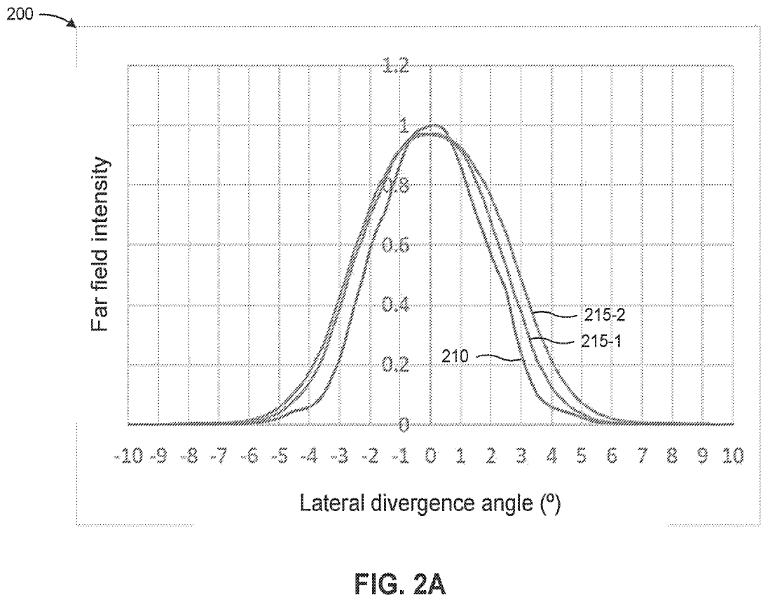

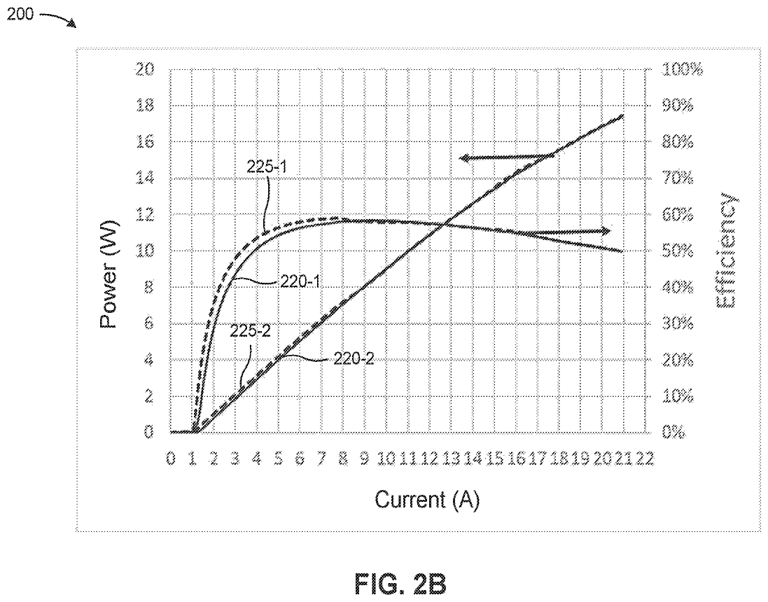

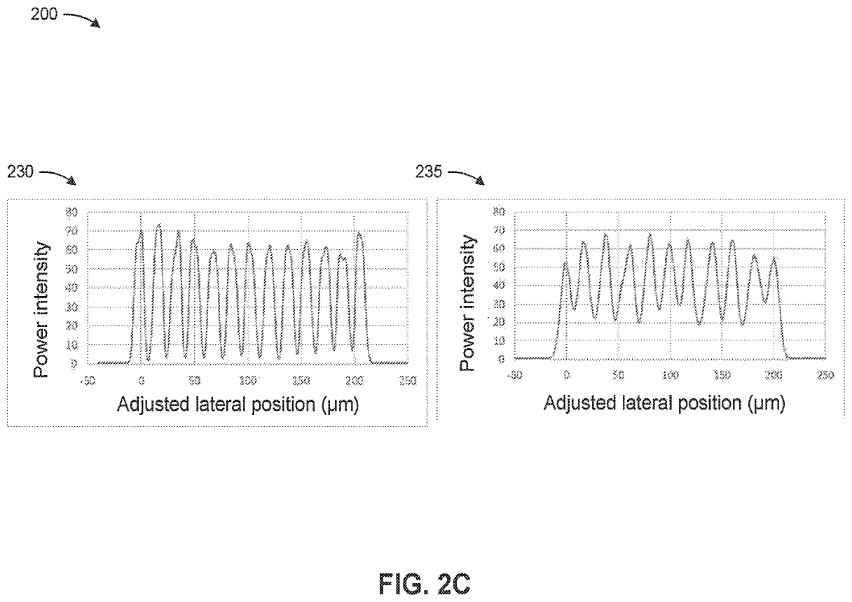

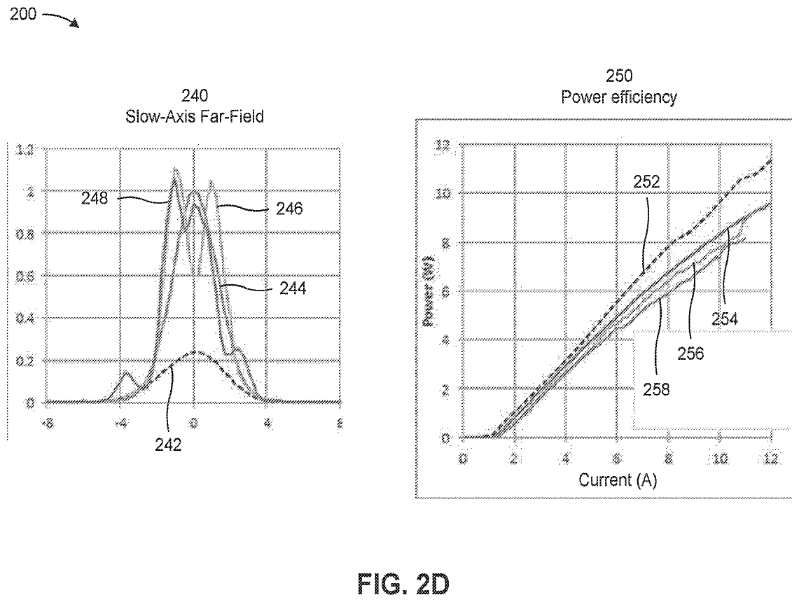

FIGS. 2A-2D are diagrams illustrating example plots 200 related to performance of a flared laser diode array described herein.

For example, FIG. 2A illustrates a plot related to lateral single mode lasing associated with the slow-axis far field patterns of different designs for the flared laser diode array described herein. In FIG. 2A, the lateral single mode lasing is shown by curves 210, 215-1, 215-2 that represent a far field intensity (in arbitrary units) as a function of a lateral divergence angle (measured in degrees). As shown in FIG. 2A, curve 210 represents the lateral single mode lasing that may occur in a design where a flared diode laser array includes eleven (11) emitters with an emitter width of 20 μm and operation at a current of 21 amps (A), and curves 215-1 and 215-2 represent the lateral single mode lasing that may occur in designs that include thirteen (13) emitters with an emitter width of 15 μm. Furthermore, curves 215-1 and 215-2 may differ in that curve 215-1 is associated with operation at a current of 13.9 A and curve 215-2 is associated with operation at a current of 21 A. As shown in FIG. 2A, the two curves 215-1 and 215-2 are very close to each other despite covering a very large current and/or power range, and are almost immune to a “blooming” effect due to single mode lasing. At a 95% power envelope level, the full divergence angles of flared laser diode arrays with 15 μm and 20 μm emitter widths are 8.5° and 7.5°, respectively.

Furthermore, FIGS. 2B-2D illustrate additional properties of flared laser diode arrays with different design parameters. In particular, FIG. 2B illustrates an example of light-current-voltage (LIV) measurements, including a first set of curves 220-1 and 220-2 (the solid lines) for a flared laser diode array with a 20 μm emitter width at a front (output) facet and a second set of curves 225-1 and 225-2 (the dashed lines) for a flared laser diode array with a 15 μm emitter width at the front (output) facet. Furthermore, FIG. 2C depicts an example 230 of a near field for a flared laser diode array with a 15 μm emitter width at the front facet and an example 235 of a near field for a flared laser diode array with a 20 μm emitter width at the front facet.

In addition, FIG. 2D illustrates the potential impact of the spacing or gap provided between adjacent emitters, where an insufficient gap between adjacent emitters may result in evanescent coupling and therefore interference spikiness in a far field. For example, in FIG. 2D, plot 240 illustrates a slow-axis far-field, including a curve 242 that represents the slow-axis far-field for a single emitter and curves 244, 246, 248 that represent the slow-axis far-field for a flared laser diode array with 8 laser stripes. In particular, curve 244 shows the slow-axis far-field for a flared laser diode array with an aperture of 200 μm and a 4 μm gap between adjacent emitters, curve 246 shows the slow-axis far-field for a flared laser diode array with an aperture of 170 μm and a 0 μm gap (e.g., no gap) between adjacent emitters, and curve 248 shows the slow-axis far-field for a flared laser diode array with an aperture of 140 μm and a negative 4 μm gap (e.g., a 4 μm overlap) between adjacent emitters. As shown, the curve 244 associated with a gap separating the adjacent emitters exhibits a good far field, but there is interference spikiness in the curves 246 and 248 associated with 0 μm and negative 4 μm gaps between adjacent emitters. Similarly, plot 250 depicts power efficiency for different design parameters, including a curve 252 that represents the slow-axis far-field for a single emitter and curves 254, 256, 258 that represent the power efficiency for a flared laser diode array with 8 laser stripes based on different spacings between adjacent emitters. In particular, curve 254 shows the power efficiency for a flared laser diode array with an aperture of 200 μm and a 4 μm gap between adjacent emitters, curve 256 shows the power efficiency for a flared laser diode array with an aperture of 170 μm and a 0 μm gap (e.g., no gap) between adjacent emitters, and curve 258 shows the power efficiency for a flared laser diode array with an aperture of 140 μm and a negative 4 μm gap (e.g., a 4 μm overlap) between adjacent emitters. As shown, the power deficiency generally decreases as the size of the gap between adjacent emitters decreases.

Accordingly, as shown by the far field Gaussian curves in FIG. 2A, the flared laser diode array described herein may provide strictly single lateral mode lasing. Because the chips with emitter widths of 15 μm and 20 μm have slow-axis divergence angles of 8.5° and 7.5°, respectively, the calculated beam parameter product for a slow-axis (BPPsA) of both types of emitters are ˜0.56 millimeter-milliradians (mm-mrad) and ˜0.65 mm-mrad, or M_{SA}²<2 for both cases. The slow-axis divergence angles of both chips increase much slower with current than the traditional BALs. As shown in FIG. 2B, the chips maintain above 50% power conversion efficiency (PCE) at 17 W. Although the PCE level is ˜10% lower than the SEAL design described above, the PCE level is ˜20% higher than the SCOWL design. In some implementations, the efficiency of the lasers can be improved to 55-60% by further optimization of epitaxial structures, laser coatings, and/or other parameters. Furthermore, FIG. 2C shows the near fields of the chips with 15 μm and 20 μm emitter widths, with 13 and 11 discrete emitters, respectively. Due to the much larger emitter width and the very high fill factor at the laser front facets, reliable operation of a laser power density above 1000 W per cm may be provided by the laser structures described herein, which provides a significantly improved laser power density that can be very beneficial for laser systems with a lower cost per W by saving semiconductor material costs and optical module sizes.

As indicated above, FIGS. 2A-2D are provided as examples. Other examples may differ from what is described with respect to FIGS. 2A-2D.

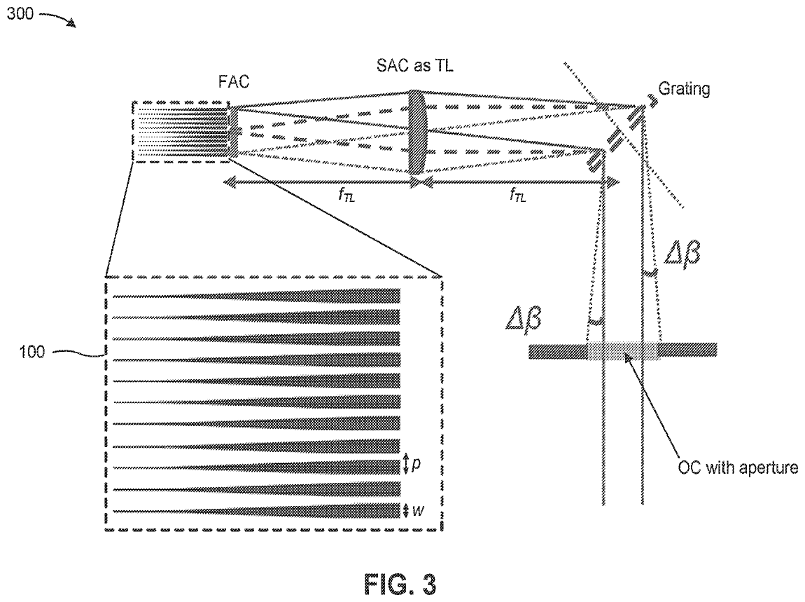

FIG. 3 is a diagram illustrating an example implementation 300 of a multi-wavelength source that includes a flared laser diode array 100 described herein. For example, as described herein, the laser diode array 100 (shown in an expanded form in the lower left of FIG. 3) may include a cavity having a rear facet and a front (e.g., output) facet and multiple emitters that are transversely single mode and disposed within the cavity. In some implementations, the multiple emitters each include a seeding section having a constant emitter width that is single mode at the rear facet and a flared section having a monotonically expanding emitter width that increases adiabatically over a majority of a length of the cavity such that a set of beamlets output from the multiple emitters are single mode at the front facet. As further shown, the multi-wavelength source includes a fast-axis collimation (FAC) lens to collimate the set of beamlets in a fast-axis direction, a slow-axis collimation (SAC) lens to collimate the set of beamlets in a slow-axis direction, an output coupler (OC) with an aperture, and a grating to direct the set of beamlets toward the output coupler.

In some implementations, the SAC lens may be located one focal length away from the front facets of the laser diode array 100, and the SAC lens may serve as a Fourier transformation lens (TL) that can change the different lateral positions of the beamlets into different incident angles on the grating, which is located one focal length away from the SAC lens. After all the beamlets have passed through the FAC lens, the SAC lens, and the grating, the near fields and the far fields of all of the beamlets may be overlapped together under the proper optical feedback. Accordingly, the multi-wavelength source can boost the brightness of the beamlets by N times, where N is a quantity of the beamlets. However, to stabilize the lateral multi-wavelength source, the duty cycle of the beamlet array output by the flared laser diode array 100 (e.g., the emitter width w divided by the beamlet pitch p) may satisfy (e.g., be less than or equal to) a threshold, such as 70%.

As indicated above, FIG. 3 is provided as an example. Other examples may differ from what is described with regard to FIG. 3. The number and arrangement of devices shown in FIG. 3 is provided as an example. In practice, there may be additional devices, fewer devices, different devices, or differently arranged devices than those shown in FIG. 3. Furthermore, two or more devices shown in FIG. 3 may be implemented within a single device, or a single device shown in FIG. 3 may be implemented as multiple, distributed devices. Additionally, or alternatively, a set of devices (e.g., one or more devices) shown in FIG. 3 may perform one or more functions described as being performed by another set of devices shown in FIG. 3.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A laser diode array, comprising:
a cavity that includes a rear facet and a front facet; and
multiple emitters that are transversely single mode and disposed within the cavity, wherein the multiple emitters each include:
a seeding section having a constant emitter width that is single mode at the rear facet, and
a flared section having a monotonically expanding emitter width that increases adiabatically over a majority of a length of the cavity such that outputs from the multiple emitters are single mode at the front facet,
wherein the emitter width is less than twenty micrometers at the front facet.

2. The laser diode array of claim 1, wherein the constant value of the emitter width in the seeding section satisfies a single mode seeding threshold that is based on one or more of a lasing wavelength, an effective index of a single mode in a waveguide region of each emitter, or a refractive index outside the waveguide region of each emitter.

3. The laser diode array of claim 1, wherein the flared section has a parabolic or logarithmic shape such that a rate at which the emitter width expands over the flared section is a constant fraction or a near-constant fraction of a numerical aperture of a beam.

4. The laser diode array of claim 1, wherein the flared section has a linear shape such that the emitter width expands over the flared section at a constant rate.

5. The laser diode array of claim 1, wherein the flared section includes multiple sub-sections in which the emitter width expands at different linear rates.

6. The laser diode array of claim 1, wherein the flared sections follow a serrated pattern such that a gain is maximized in a central region of each emitter and reduced in regions that are near edges of each emitter.

7. The laser diode array of claim 1, wherein a rate at which the emitter width expands near the seeding section is less than a rate at which the emitter width expands near the front facet.

8. The laser diode array of claim 1, wherein gaps separate adjacent emitters in the laser diode array to prevent evanescent coupling between the adjacent emitters.

9. The laser diode array of claim 1, wherein the emitter width is at least fifteen micrometers at the front facet.

10. The laser diode array of claim 1, wherein the rear facet has a highly reflective coating and the front facet has a low reflectivity coating.

11. A multi-wavelength source, comprising:
a laser diode array that includes:
a cavity that includes a rear facet and a front facet; and
multiple emitters that are transversely single mode and disposed within the cavity, wherein the multiple emitters each include:
a seeding section having a constant emitter width that is single mode at the rear facet, and
a flared section having a monotonically expanding emitter width that increases adiabatically over a majority of a length of the cavity such that a set of beamlets output from the multiple emitters are single mode at the front facet,
wherein the emitter width is less than twenty micrometers at the front facet;
a fast-axis collimation (FAC) lens to collimate the set of beamlets in a fast-axis direction;
a slow-axis collimation (SAC) lens to collimate the set of beamlets in a slow-axis direction; and
a grating to direct the set of beamlets toward an output coupler.

12. The multi-wavelength source of claim 11, wherein the emitter width expands in the flared section of each emitter by at least ten times a wavelength associated with the laser diode array.

13. The multi-wavelength source of claim 11, wherein gaps separate adjacent emitters in the laser diode array to prevent evanescent coupling between the adjacent emitters.

14. The multi-wavelength source of claim 11, wherein the emitter width is at least fifteen micrometers at the front facet.

15. An emitter, comprising:
a rear facet;
a front facet; and
a transversely single mode cavity that includes a seeding section and a flared section arranged between the rear facet and the front facet,
wherein the seeding section has a constant emitter width that is single mode at the rear facet,
wherein the flared section has a monotonically expanding emitter width that increases adiabatically over a majority of a length of the cavity such that an output from the emitter is single mode at the front facet, and
wherein the emitter width is less than twenty micrometers at the front facet.

16. The emitter of claim 15, wherein the flared section has a parabolic or logarithmic shape such that a rate at which the emitter width expands over the flared section is a constant fraction or a near-constant fraction of a numerical aperture of a beam.

17. The emitter of claim 15, wherein the flared section has a linear shape such that the emitter width expands over the flared section at a constant rate.

18. The emitter of claim 15, wherein the flared section includes multiple sub-sections in which the emitter width expands at different linear rates.

19. The emitter of claim 15, wherein a rate at which the emitter width expands near the seeding section is less than a rate at which the emitter width expands near the front facet.

20. The emitter of claim 15, wherein the emitter width is at least fifteen micrometers at the front facet.
